(19) United States
(12) Patent Application Publication
(10) Pub. No.: US 2024/0332296 A1
(43) Pub. Date: Oct. 3, 2024

(54) FORKSHEET DEVICE WITH ACCURATE GATE EXTENSION FOR REDUCED PARASITIC CAPACITANCE

(71) Applicant: INTERNATIONAL BUSINESS MACHINES CORPORATION, ARMONK, NY (US)

(72) Inventors: Ruilong Xie, Niskayuna, NY (US); Julien Frougier, Albany, NY (US); Huimei Zhou, Albany, NY (US); Alexander Reznicek, Troy, NY (US)

(21) Appl. No.: 18/193,595

(22) Filed: Mar. 30, 2023

(51) Int. Cl. H01L 27/092; H01L 21/8238; H01L 29/06; H01L 29/423; H01L 29/66; H01L 29/775; H01L 29/786

(52) U.S. Cl. CPC H01L 27/092; H01L 21/823807; H01L 21/823878; H01L 29/0673; H01L 29/42392; H01L 29/66439; H01L 29/66545; H01L 29/775; H01L 29/78696

(57) ABSTRACT

A semiconductor device includes a vertical insulator pillar extending from the substrate. A first stack of horizontal sheets of a first channel device is coupled to a lateral first side of the vertical insulator pillar and a second stack of horizontal sheets of a second channel device is coupled to a lateral second side of the vertical insulator pillar, opposite the first stack of horizontal sheets. A first gate stack is wrapped around the first stack of horizontal sheets. A second gate stack is wrapped around the second stack of horizontal sheets. A first gate extension is coupled to a center portion of the first gate stack and extending laterally away from the second gate stack and a second gate extension is coupled to a center portion of the second gate stack and extending laterally away from the first gate stack.

### BACKGROUND

### Technical Field

The present disclosure generally relates semiconductor fabrication methods and resulting structures, and more specifically, to fabrication methods and resulting forksheet semiconductor devices.

### Description of the Related Art

In contemporary semiconductor device fabrication processes, a large number of semiconductor devices, such as n-type field effect transistors (nFETs) and p-type field effect transistors (pFETs), are fabricated on a single wafer. Non-planar transistor device architectures (e.g., fin-type FETs (FinFETs) and nanosheet FETs) can provide increased device density and increased performance over planar transistors. FinFETs are non-planar, three-dimensional (3D) devices that include a fin-shaped element that defines the source, drain, and channel regions of the FinFET. A gate stack is formed over and around a central region of the fin-shaped element, and the portion of the fin that is under the gate stack functions as the FinFET channel. The portions of the fin-shaped element that are not under the gate stack function as the source region and the drain region, respectively. Nanosheet transistors are similar to FinFETs except the channel portion of the fin is formed as multiple spaced-apart channel nanosheets, and the gate stack wraps around the full perimeter of each nanosheet channel region for improved control of channel current flow. Nanosheet transistors enable full depletion in the nanosheet channel regions and reduce short-channel effects.

### SUMMARY

According to an embodiment of the present disclosure, a semiconductor device includes a vertical insulator pillar extending from a substrate. A first stack of horizontal sheets of a first channel device is coupled to a lateral first side of the vertical insulator pillar. A second stack of horizontal sheets of a second channel device is coupled to a lateral second side of the vertical insulator pillar, opposite the first stack of horizontal sheets. A first gate stack is wrapped around the first stack of horizontal sheets. A second gate stack is wrapped around the second stack of horizontal sheets. A first gate extension is coupled to a center portion of the first gate stack and extending laterally away from the second gate stack. A second gate extension is coupled to a center portion of the second gate stack and extending laterally away from the first gate stack.

In one embodiment, a first gate contact extends from a top of the semiconductor device to the first gate extension, and a second gate contact extending from the top of the semiconductor device to the second gate extension.

In one embodiment, at least a portion of the vertical insulator pillar is embedded in the substrate.

In one embodiment, a third extension is on a top portion of the first gate stack abutting the vertical insulator pillar, and a fourth extension on a top portion of the second gate stack abutting the vertical insulator pillar.

In one embodiment, a common gate contact is coupled to a top portion of the third extension of the gate stack, a top portion of the fourth extension of the gate stack, and a top of the vertical insulator pillar.

In one embodiment, a first gate cut region is adjacent the first gate stack and extending from a top of the semiconductor device to a first shallow trench isolation (STI) on top of the substrate. A second gate cut region is adjacent the second gate stack and extending from the top of the semiconductor device to a second shallow trench isolation (STI) on top of the substrate.

In one embodiment, the first stack and the second stack of horizontal sheets each are of a Silicon Germanium (SiGe) nanosheet stack.

In one embodiment, a lateral side width of the first gate stack overlapping from the first stack of horizontal sheets is substantially similar to a gap between each of the sheets of the first stack of horizontal sheets. A lateral side width of the second gate stack overlapping from the second stack of horizontal sheets is substantially similar to a gap between each of the sheets of the second stack of horizontal sheets.

In one embodiment, a shallow trench isolation (STI) extends from the substrate to a middle portion of the first gate stack and the second gate stack.

In one embodiment, the semiconductor device is a forksheet device. The first channel device is a p-channel field effect transistor (pFET). The second channel device is an n-channel field effect transistor (nFET).

In one embodiment, a width of the vertical insulator pillar is below 10 nm.

In one embodiment, the first gate stack is not directly coupled to the second gate stack and is separated by the vertical insulator pillar.

According to one embodiment, method of manufacturing a semiconductor includes providing a first stack of horizontal sheets of a first transistor device and a second stack of horizontal sheets of a second transistor device, coupled to opposite sides of a vertical insulator pillar. For each of the first and second stack of horizontal sheets, a raised shallow trench isolation (STI) is provided on a lateral first side, opposite the vertical insulator pillar. A sacrificial gate is formed that wraps around channels of the nanosheet stack. A sacrificial gate liner of the sacrificial gate is removed from a top portion of the vertical insulator pillar. A gate trench opening is formed to access the sacrificial gate. A replacement gate stack is formed wrapped around the horizontal sheets. A gate extension is formed above the raised STI.

In one embodiment, the first transistor is a p-channel field effect transistor (pFET), the second transistor is an n-channel field effect transistor (nFET), and the first stack and the second stack of horizontal sheets each are made of a Silicon Germanium (SiGe) nanosheet stack.

In one embodiment, sacrificial gate liner from the top portion of the vertical insulator pillar is removed by chamfering.

In one embodiment, a first gate contact is provided between a top surface of the semiconductor device and the gate extension of the first nanosheet stack. A second gate contact is provided between the top surface of the semiconductor device and the gate extension of the second nanosheet stack.

In one embodiment, at least a portion of the vertical insulator pillar is embedded in the substrate.

In one embodiment, for each of the first and second stack of horizontal sheets, an additional extension is provided on a top portion of the replacement gate stack, abutting the vertical insulator pillar.

In one embodiment, a common gate contact is formed coupled to a top portion of each gate stack and a top of the vertical insulator pillar.

According to one embodiment, a forksheet device includes a vertical insulator pillar. A first stack of horizontal sheets of a p-channel field effect transistor (pFET) is coupled to a lateral first side of the vertical insulator pillar.

A second stack of horizontal sheets of a n-channel field effect transistor (nFET) is coupled to a lateral second side of the vertical insulator pillar, opposite the first stack of horizontal sheets. A first gate stack is wrapped around the first stack of horizontal sheets. A second gate stack is wrapped around the second stack of horizontal sheets. A first gate extension is coupled to a center portion of the first gate stack and extending laterally away from the second gate stack. A second gate extension is coupled to a center portion of the second gate stack and extending laterally away from the first gate stack.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIG. 1A illustrates a known nanosheet complementary metal oxide semiconductor (CMOS) device.

FIG. 1B illustrates a forksheet device with a reduced N2P space.

FIG. 2 provides a plan view of a forksheet transistor, consistent with an illustrative embodiment.

FIGS. 3A, 3B, and 3C depict a cross-section view of a semiconductor device along the lines X1, Y1, and Y2, respectively, of FIG. 2, consistent with an illustrative embodiment.

FIGS. 4A, 4B, and 4C depict a cross-section view of a semiconductor device along the lines X1, Y1, and Y2, respectively, of FIG. 2, after a middle pillar and shallow trench isolation (STI) formation, consistent with an illustrative embodiment.

FIGS. 5A, 5B, and 5C depict a cross-section view of a semiconductor device along the lines X1, Y1, and Y2, respectively, of FIG. 2, after the first sacrificial nanosheet is removed, consistent with an illustrative embodiment.

FIGS. 6A, 6B, and 6C depict a cross-section view of a semiconductor device along the lines X1, Y1, and Y2, respectively, of FIG. 2, after selective SiGe growth to define the gate extension, consistent with an illustrative embodiment.

FIGS. 7A, 7B, and 7C depict a cross-section view of a semiconductor device along the lines X1, Y1, and Y2, respectively, of FIG. 2, after an additional shallow trench isolation (STI) deposition on top of the first deposition of STI, consistent with an illustrative embodiment.

FIGS. 8A, 8B, and 8C depict a cross-section view of a semiconductor device along the lines X1, Y1, and Y2, respectively, of FIG. 2, after removal of the hard mask (HM) layer, consistent with an illustrative embodiment.

FIGS. 9A, 9B, and 9C depict a cross-section view of a semiconductor device along the lines X1, Y1, and Y2, respectively, of FIG. 2, after a gate deposition and gate patterning, consistent with an illustrative embodiment.

FIGS. 10A, 10B, and 10C depict a cross-section view of a semiconductor device along the lines X1, Y1, and Y2, respectively, of FIG. 2, after formation of gate spacers, inner spacers, and source and drain epitaxial formation, consistent with an illustrative embodiment.

FIGS. 11A, 11B, and 11C depict a cross-section view of a semiconductor device along the lines X1, Y1, and Y2, respectively, of FIG. 2, after an interlayer dielectric deposition, consistent with an illustrative embodiment.

FIGS. 12A, 12B, and 12C depict a cross-section view of a semiconductor device along the lines X1, Y1, and Y2, respectively, of FIG. 2, after an opening is created to access trenches, consistent with an illustrative embodiment.

FIGS. 13A, 13B, and 13C depict a cross-section view of a semiconductor device along the lines X1, Y1, and Y2, respectively, of FIG. 2, after additional processing, consistent with an illustrative embodiment.

FIGS. 14A, 14B, and 14C depict a cross-section view of a semiconductor device along the lines X1, Y1, and Y2, respectively, of FIG. 2, after a high-k metal gate (HKMG) formation, consistent with an illustrative embodiment.

FIGS. 15A, 15B, and 15C depict a cross-section view of a semiconductor device along the lines X1, Y1, and Y2, respectively, of FIG. 2, after excess metal is recessed and a self-aligned contact (SAC) cap is formed, consistent with an illustrative embodiment.

FIGS. 16A, 16B, and 16C depict a cross-section view of a semiconductor device along the lines X1, Y1, and Y2, respectively, of FIG. 2, after additional processing for separate gate devices, consistent with an illustrative embodiment.

FIG. 16D provides an enlarged view of FIG. 16C, consistent with an illustrative embodiment.

FIGS. 17A, 17B, and 17C depict a cross-section view of a semiconductor device along the lines X1, Y1, and Y2, respectively, of FIG. 2, for shared gate devices, consistent with an illustrative embodiment.

FIG. 17D provides an enlarged view of FIG. 17C, consistent with an illustrative embodiment.

FIG. 18 illustrates an example of method of manufacturing a semiconductor device, consistent with an illustrative embodiment.

### DETAILED DESCRIPTION

### Overview

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. Similarly, an element described as “on top of” of another element may mean either that the element is positioned above and is not necessarily in direct contact with the underlying element. The device may be otherwise oriented (rotated 90 degrees or viewed or referenced at other directions) and the spatially relative descriptors used herein should be interpreted accordingly.

As used herein, the terms “lateral”, “planar”, and “horizontal” describe an orientation parallel to a first surface of a chip or substrate. In the disclosure herein, the “first surface” may be the top layer of a semiconductor device where individual circuit devices are patterned in the semiconductor material.

As used herein, the term “vertical” describes an orientation that is arranged perpendicular to the first surface of a chip, chip carrier, chip substrate, or semiconductor body.

As used herein, the terms “coupled” and/or “electrically coupled” are not meant to mean that the elements must be directly coupled together-intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together. The phrase “electrically connected” does not necessarily mean that the elements must be directly in physical contact together-intervening elements may be provided between the “connected” or “electrically connected” elements.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. Nor does describing an element as “first” or “second,” etc., necessarily mean that there is an order or priority to any of the elements. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

Turning now to a description of technologies that are more specifically relevant to the present disclosure, transistors are semiconductor devices commonly found in a wide variety of ICs. A transistor is essentially a switch. When a voltage is applied to a gate of the transistor that is greater than a threshold voltage, the switch is turned ON, and current flows through the transistor. When the voltage at the gate is less than the threshold voltage, the switch is OFF, and current does not flow through the transistor.

Typical semiconductor devices are formed using active regions of a wafer. The active regions are defined by isolation regions used to separate and electrically isolate adjacent semiconductor devices. For example, in an IC having a plurality of metal oxide semiconductor field effect transistors (MOSFETs), each MOSFET has a source and a drain that are formed in an active region of a semiconductor layer by implanting n-type or p-type impurities in the layer of semiconductor material. Disposed between the source and the drain is a channel (or body) region. Disposed above the body region is a gate electrode. The gate electrode and the body are spaced apart by a gate dielectric layer.

MOSFET-based ICs are fabricated using so-called complementary metal oxide semiconductor (CMOS) fabrication technologies. In general, CMOS is a technology that uses complementary and symmetrical pairs of p-type and n-type MOSFETs to implement logic functions. The channel region connects the source and the drain, and electrical current flows through the channel region from the source to the drain. The electrical current flow is induced in the channel region by a voltage applied at the gate electrode.

The wafer footprint of an FET is related to the electrical conductivity of the channel material. If the channel material has a relatively high conductivity, the FET can be made with a correspondingly smaller wafer footprint. A known method of increasing channel conductivity and decreasing FET size is to form the FET as a non-planar FinFET architecture, wherein the channel of the FinFET is implemented as a fin-shaped structure, and wherein a gate stack is wrapped around sidewalls and a top surface of a central region of the fin-shaped structure. The portion of the fin-shaped structure that is under the gate stack functions as the channel, and the portions of the fin-shaped structure that are not under the gate stack are doped to function as the source region and the drain region, respectively. In some implementations, the fin-shaped structure is Si, and the S/D regions of the fin are formed as doped SiGe. The use of doped SiGe to form the S/D regions provides desirable device characteristics, including the introduction of strain at the various interfaces between SiGe and Si in the transistor.

Another approach in increasing channel conductivity and decreasing FET size is to form the channel as a nanosheet structure. For example, a gate-all-around (GAA) nanosheet FET is a known architecture for providing a relatively small FET footprint by forming the channel region as a series of nanosheets. In a known GAA configuration, a nanosheet-based FET includes a source region, a drain region and stacked nanosheet channels between the source and drain regions. A gate surrounds the stacked nanosheet channels and regulates electron flow through the nanosheet channels between the source and drain regions. GAA nanosheet FETs are fabricated by forming alternating layers of channel nanosheets and sacrificial layers. The sacrificial layers are released from the channel nanosheets before the FET device is finalized. For n-type FETs, the channel nanosheets are typically Si and the sacrificial layers are typically SiGe. For p-type FETs, the channel nanosheets can be SiGe and the sacrificial layers can be Si. In some implementations, the channel nanosheet of a p-type FET can be SiGe or Si, and the sacrificial layers can be Si or SiGe. Similar to FinFET architectures, the S/D regions of a GAA nanosheet architecture can be formed from doped SiGe. Forming the S/D regions from SiGe, and the use of multiple layered SiGe/Si sacrificial/channel nanosheets (or Si/SiGe sacrificial/channel nanosheets) provide desirable device characteristics, including the introduction of strain at the interface between SiGe and Si, as mentioned above.

As semiconductor devices continue to decrease in size, it has become desirable to provide distances between the nFET and pFET fins, sometimes referred to as the “N2P space.” Providing N2P spaces at small dimensions, particularly at below 10 nm, can present challenges to communicating with the pFET section and the nFET section. Specifically, N2P spaces on this order reduce the process window within which contact structures connecting the nFET section and pFET section do not electrically short with one another. N2P spaces on this order also reduce the process window within which the resistance and capacitance (R/C) electrical characteristics, sometimes referred to as parasitic components of the semiconductor device, are acceptable. While the process window can be broadened by positioning the contact structure at locations laterally offset from the N2P space, such positioning increases the electrical resistance between the contact structures and the respective pFET section and nFET section, offsetting the improvement in process window and/or electrical characteristics of the multilayer integrated circuit (IC) device.

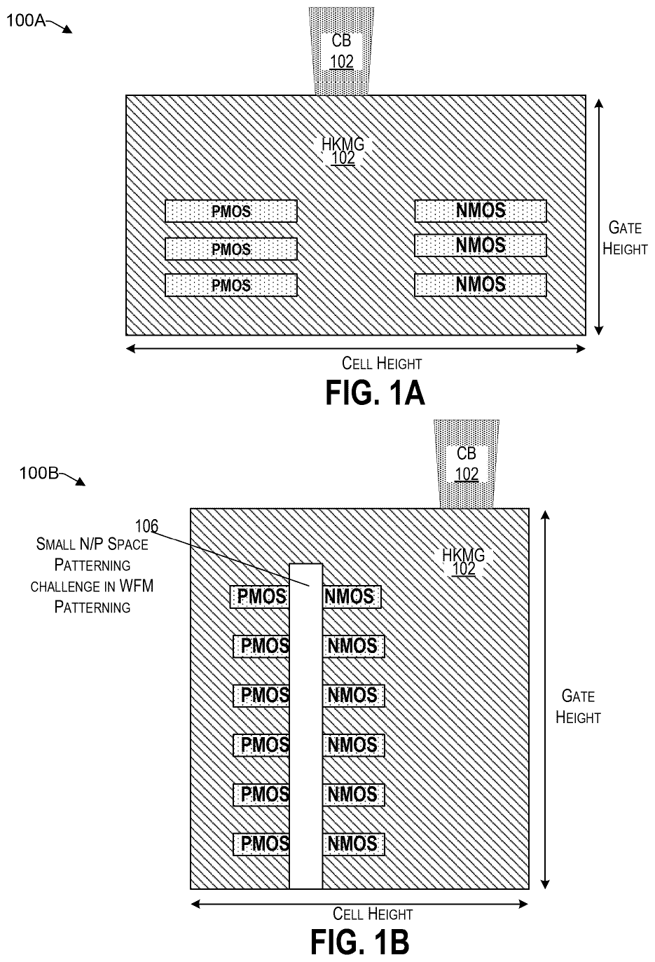

Reference now is made to FIG. 1A, which illustrates a known nanosheet complementary metal oxide semiconductor (CMOS) device 100A. The nanosheet device 100A is similar to a FinFET, except that the channel portion of the fin is formed as multiple spaced-apart channel nanosheets, and the gate stack wraps around the full permitter of each nanosheet channel region for improved control of channel current flow. Nanosheet transistor 100A is illustrated as a CMOS device having a PMOS and NMOS nanosheets configured in stacks that are surrounded by a high-k dielectric metal gate 102. There is a gate contact (CB) 102 coupled to the gate. As illustrated, there is a relatively large N2P distance, thereby increasing the cell height, while the gate height is relatively small. Also, the cell height is relatively large with respect to the gate height.

More recently, the trend to continue reducing the footprint of FET devices has led to the development of forked nanosheet semiconductor devices, also referred to as “forksheet devices.” In this regard, reference is made to FIG. 1B, which illustrates a forksheet CMOS device 100B with a reduced N2P space, consistent with an illustrative embodiment. As illustrated in FIG. 1B, the cell height is relatively small with respect to the gate height.

The forksheet device 100B implements nanosheets that are controlled by a tri-gate forked structure. The tri-gate forked structure is realized by forming a dielectric wall 106 (sometimes referred to herein as a vertical insulator) between the P- and NMOS devices. The dielectric wall physically isolates the p-gate trench from the n-gate trench, allowing much tighter N2P spacing that facilitates superior area and performance scalability compared to traditional nanosheet devices (e.g., 100A). To achieve an adequate effective channel width for the forksheet device at aggressively scaled cell height, Applicants recognize that the number of stack should be increased as compared to nanosheet technology. However, increasing the stack height increases the parasitic capacitance, as the gate heigh increases.

In one aspect, the teachings herein provide an advanced transistor implemented as a forksheet device with substantially reduced parasitic capacitance and methods of creation thereof. The techniques described herein may be implemented in a number of ways. Example implementations are provided below with reference to the following figures.

### Example Methodology of Manufacture of Improved Forksheet Device

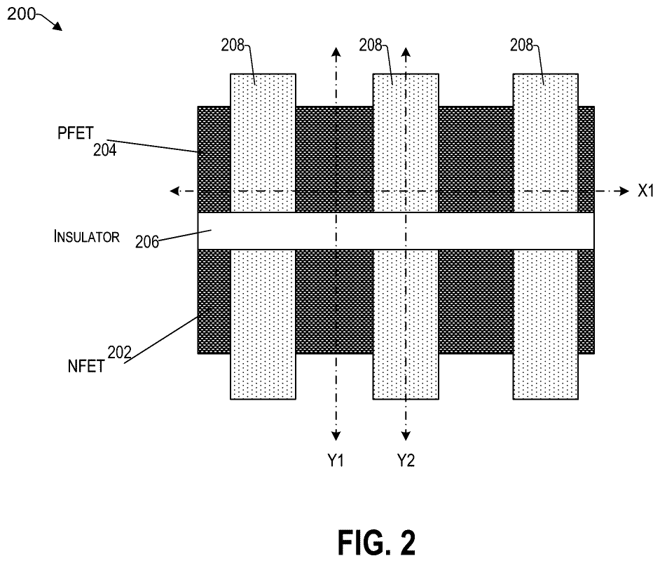

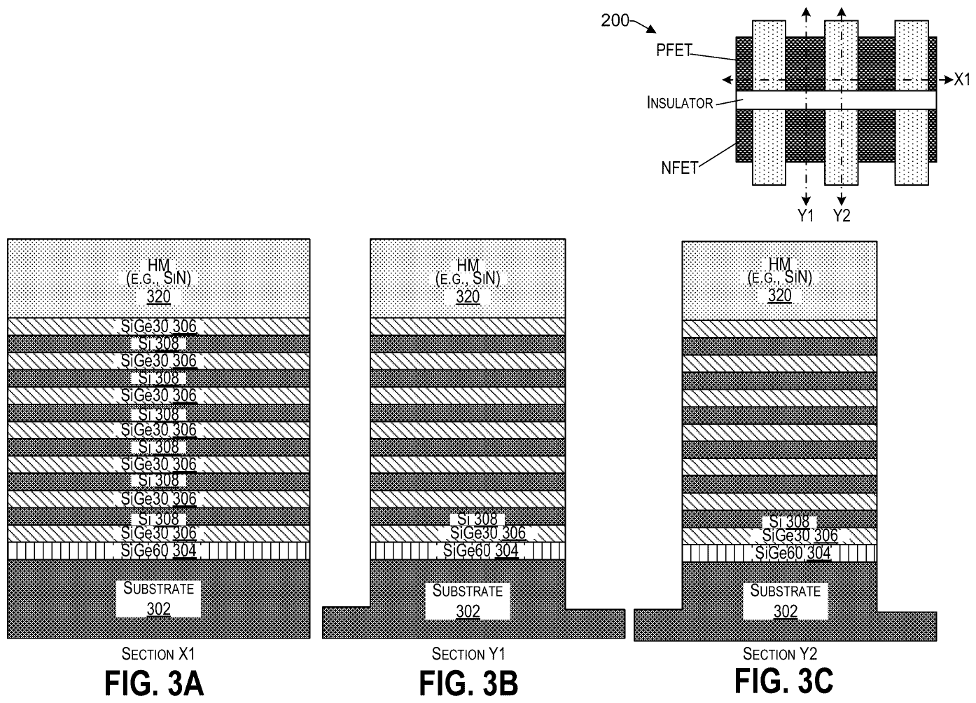

With the foregoing overview of the considerations related to forksheet devices, it may be helpful to describe an example process of creating a forksheet device. The discussion below provides an example process of manufacturing a forksheet device having a particular gate extension for reduced parasitic capacitance. FIG. 2 provides a plan view of a forksheet transistor, while FIGS. 3 to 17 provide various cross-section views at different manufacturing steps the forksheet device of FIG. 2. More specifically, FIG. 2 provides a plan view of the semiconductor device 200 showing an X cut line for an X-Z plane and a Y1 cut line for Y1-Z plane and a Y2 cut line for a Y2-Z plane.

The semiconductor device 200 includes a n-type field effect transistor (nFET) section 202, an p-type field effect transistor (pFET) section 204 (sometimes collectively referred to as an active region), an insulator pillar 206, and gate structures 208. The pFET section 204 is arranged on a side to the semiconductor device 200 laterally opposite the nFET section 202. The insulator pillar 206 (sometimes referred to herein as a vertical insulator pillar) is arranged laterally between the pFET section 204 and the nFET section 202 and extends longitudinally along the semiconductor device 200 between the pFET section 204 and the nFET section 202, as will be illustrated more clearly in subsequent drawings. The gate structures 208 (e.g., a gate electrodes) span the insulator pillar 206, wrap around the pFET section 204 and the nFET section 202 of the semiconductor device, and are longitudinally spaced from one another along the semiconductor device 200.

FIGS. 3A, 3B, and 3C depict a cross-section view of a semiconductor device along the lines X1, Y1, and Y2, respectively, of FIG. 2, consistent with an illustrative embodiment. More specifically, FIGS. 3A to 3D depict a material stack, according to an example embodiment. The depicted structure may include one or more nanosheet stacks located on the substrate 302. The substrates discussed herein can be the same material or different materials. Substrates can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys. The substrate 302 may already have pre-built structures (not shown) such as transistors, diodes, capacitors, resistors, interconnects, wiring, etc.

As mentioned previously, the term ‘nanosheet,’ as used herein, refers to a sheet or a layer having nanoscale dimensions. Further, the term ‘nanosheet’ is meant to encompass other nanoscale structures such as nanowires. For instance, ‘nanosheet’ can refer to a nanowire with a larger width, and/or ‘nanowire’ can refer to a nanosheet with a smaller width, and vice versa. The structure depicted in FIGS. 3A to 3B does not yet include a forksheet.

The nanosheet stack includes alternating layers of a second nanosheet material 306 and third nanosheet material, 308, as well as a first nanosheet material 304, which may be selectively removed later (e.g., sacrificial). For instance, according to an example embodiment, the first nanosheet material 304 is SiGe60 (i.e., Silicon-Germanium having 60 Germanium), the second nanosheet material 306 may be SiGe30 (i.e., Silicon-Germanium having 30% Germanium), and the third nanosheet material 308 may be Si. However, this is merely an example and other configurations and concentrations are contemplated herein. As will be described in detail below, these nanosheet materials will be used to form the channels of the present stacked nanosheet devices and a sacrificial material in between the channels. Removal of the sacrificial material releases the channels from the stack and permits gates to be formed that fully surround (e.g., wrap around) the channels in a gate-all-around configuration. Thus, it is preferable that the first, second, and third nanosheet materials have etch selectivity with respect to one another. Thus, when one serves as the channels, the other sacrificial material can be selectively removed to release the channels from the nanosheet stack. By way of example only and not by way of limitation, Si, SiGe30, and SiGe60 provide such etch selectivity. By ‘sacrificial’ it is meant that the layer, or portion thereof, is removed during fabrication of the device. By way of example only and not by way of limitation, each of the nanosheets 304, 306 and 308 in the nanosheet stack are deposited onto the substrate 302, one on top of the other, using an epitaxial growth process. According to an example embodiment, the first second and third nanosheets 304, 306, and 308 may have a thickness range from about 6 nm to 25 nm.

According to an example embodiment, sacrificial nanosheets 304 and 306 are formed from SiGe having a high germanium (Ge) content. For example, in one exemplary embodiment, a high Ge content is from about 50% Ge to about 100% Ge (i.e., pure Ge) and ranges therebetween. For instance, in one non-limiting example, one of sacrificial nanosheets (e.g., 304) is formed from SiGe60 (which has a Ge content of about 60%). Use of a higher Ge content SiGe will enable the sacrificial nanosheet 304 to be etched selective to the sacrificial nanosheet 306 in the nanosheet stack. Notably, however, the SiGe used as for the other sacrificial nanosheet material has a low Ge content. For example, in one exemplary embodiment, a low Ge content is from about 15% Ge to about 50% Ge and ranges therebetween.

FIGS. 3A to 3C depict a hardmask layer (HM) 320 on top of the nanosheet stack. The hard mask layer 320 can be made of any suitable material, such as, for example, a silicon nitride (SiN).

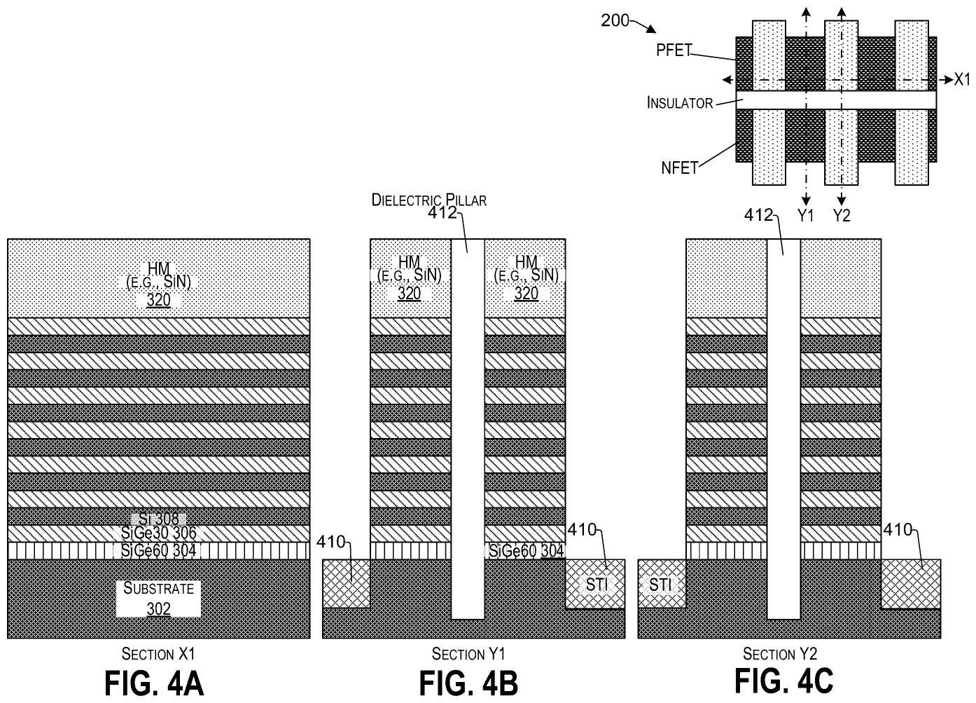

FIGS. 4A, 4B, and 4C depict a cross-section view of a semiconductor device along the lines X1, Y1, and Y2, respectively, of FIG. 2, after a center vertical pillar 412 (sometimes referred to herein as a vertical insulator pillar) and shallow trench isolation (STI) 410 formation, consistent with an illustrative embodiment. For example, an interlayer dielectric (ILD) material can be first deposited and CMP stopping on the HM 320, followed by litho patterning and etch processes to define trench openings through the HM 320 and NS stack (304, 306, 308, and 302). Then the trench openings are filled with dielectric to form vertical pillar 412. After that, the interlayer dielectric (ILD) is recessed to form shallow trench isolation (STI) 410. The shallow trench isolation 410 can help isolate one device from another. As to the vertical insulator pillar 412, sometimes referred to as a vertical insulator pillar, it is arranged between the pFET section and the nFET section and may go down into the substrate 302 and provides N2P separation. In one embodiment, the width of the vertical insulator pillar 412 is approximately 15 nm or lower. The vertical insulator pillar 412 can be formed of silicon carbide (SiC) or silicon oxycarbide (SiOC), or another suitable material, and can be formed by various processes. The vertical insulator pillar 412 extends vertically upwardly from the substrate 302 through the first nanosheet material (e.g., SiGe60) layer 304, the SiGe30 layers 306 interleaved with the Si layers 306 and the hard mask layer 320.

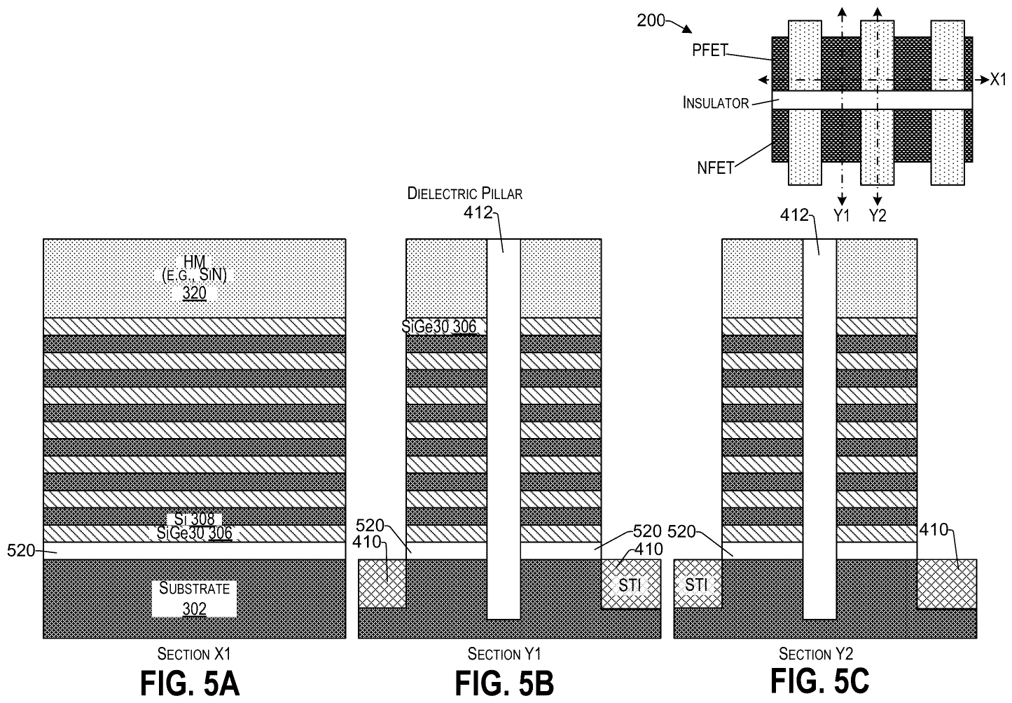

FIGS. 5A, 5B, and 5C depict a cross-section view of a semiconductor device along the lines X1, Y1, and Y2, respectively, of FIG. 2, after the first sacrificial nanosheet 304 is removed, consistent with an illustrative embodiment. Instead, a bottom dielectric isolation layer 520 is formed, for example, by conformal dielectric liner deposition followed by isotropic etch back. The bottom dielectric isolation 520 can be made of any suitable material, such as, for example, a low-k dielectric, a nitride, silicon nitride, silicon oxide, SiON, SiC, SiOCN, or SiBCN. In one embodiment, the bottom dielectric isolation layer 520 is of the same material as that of the vertical insulator pillar 412.

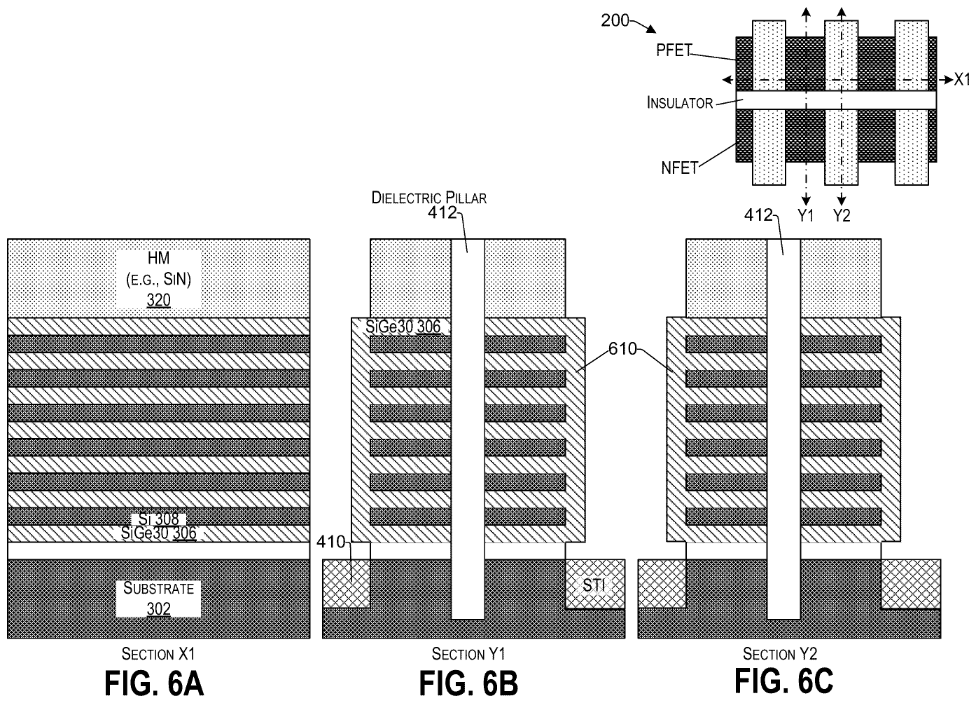

FIGS. 6A, 6B, and 6C depict a cross-section view of a semiconductor device along the lines X1, Y1, and Y2, respectively, of FIG. 2, after selective SiGe (with Ge % similar to 306) growth 610 for a later gate extension formation which will be shown in process steps later, consistent with an illustrative embodiment. The additional SiGe growth 610 is past the fins of the nanosheet stack.

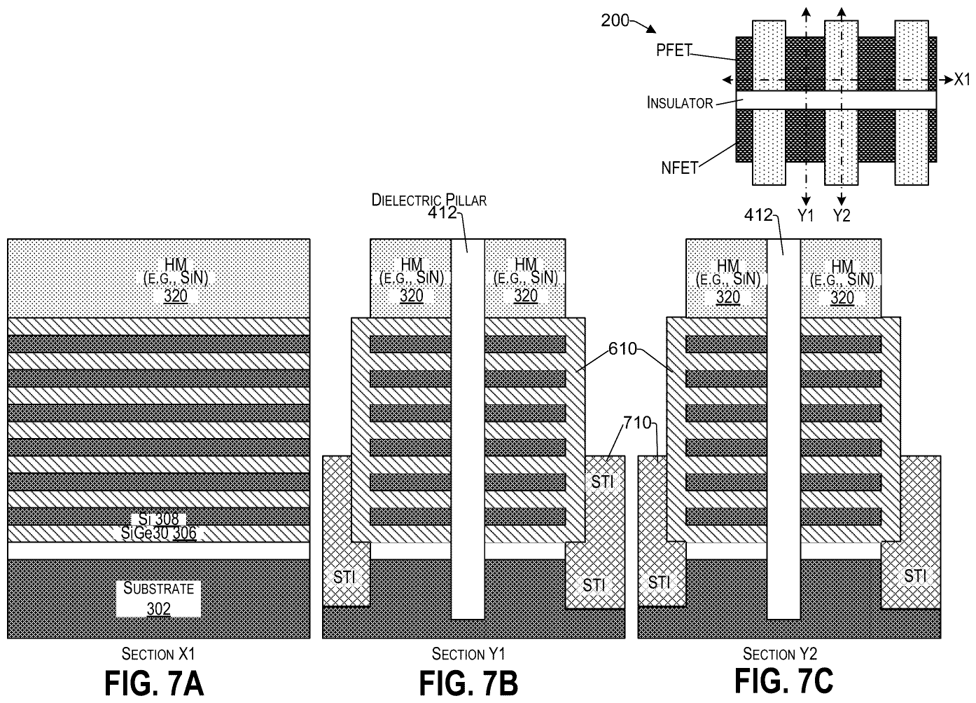

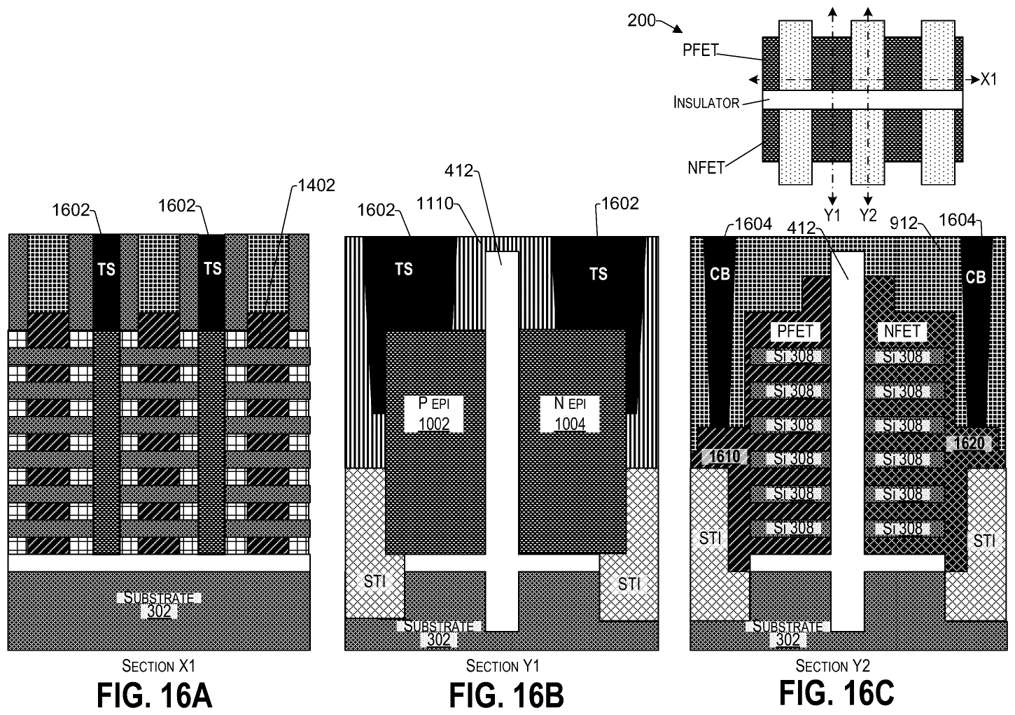

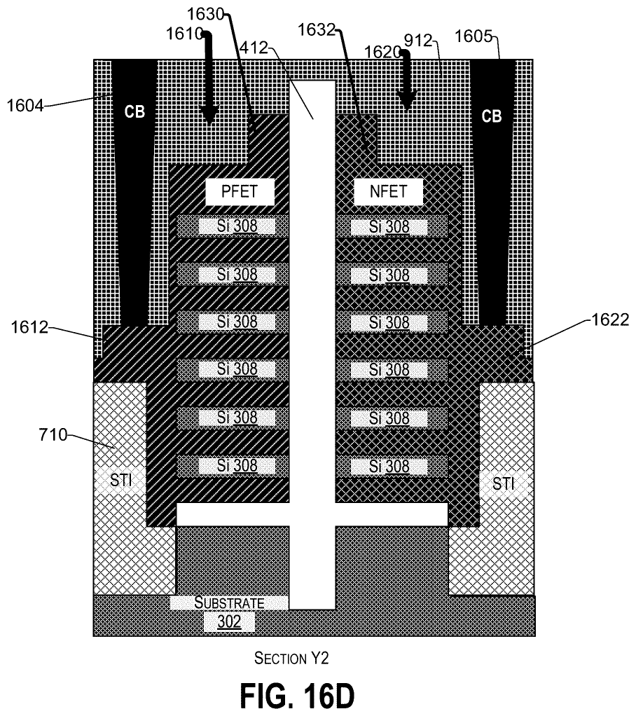

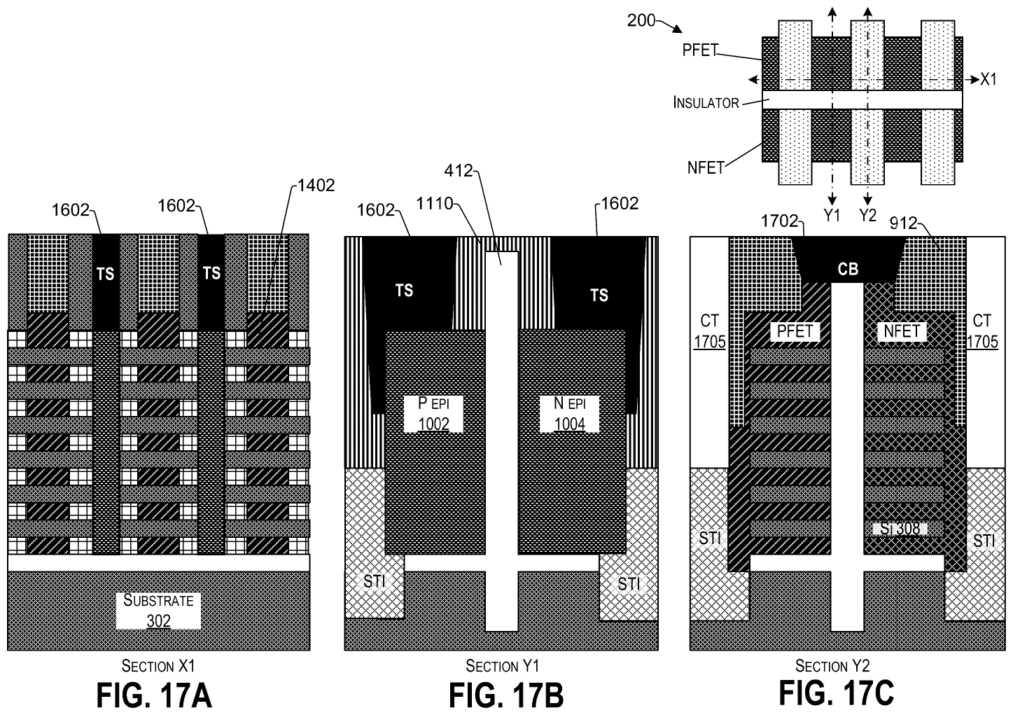

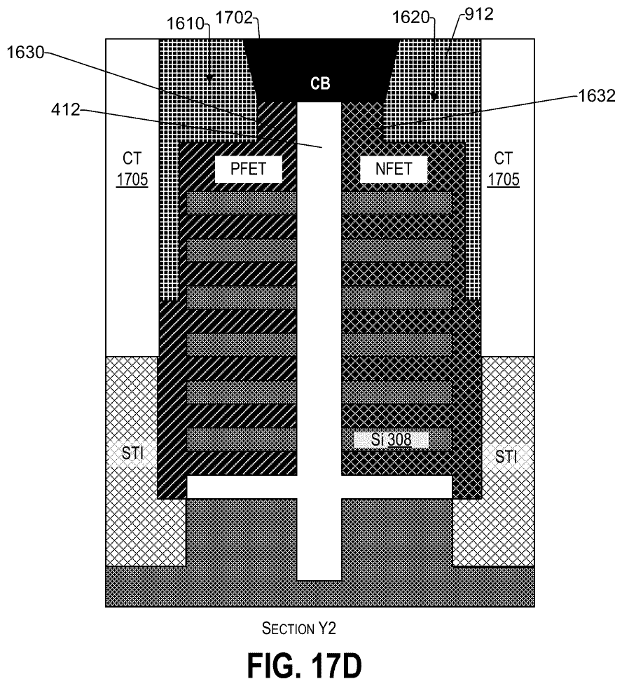

FIGS. 7A, 7B, and 7C depict a cross-section view of a semiconductor device along the lines X1, Y1, and Y2, respectively, of FIG. 2, after an additional shallow trench isolation (STI) deposition on top of the first deposition of STI, consistent with an illustrative embodiment. The STI 710 provides additional isolation between semiconductor devices. Furthermore, by virtue of using the additional STI 710, the amount of work function metal (WFM) ultimately used will be reduced, which is beneficial in reducing the capacitance between gate contacts and the final gate structure and will not require a deep drilling to provide gate contacts (CB) that may complicate the manufacturing process, as will be explained in more detail later in the context of the discussion of final structures (e.g., FIGS. 16A to 17C).

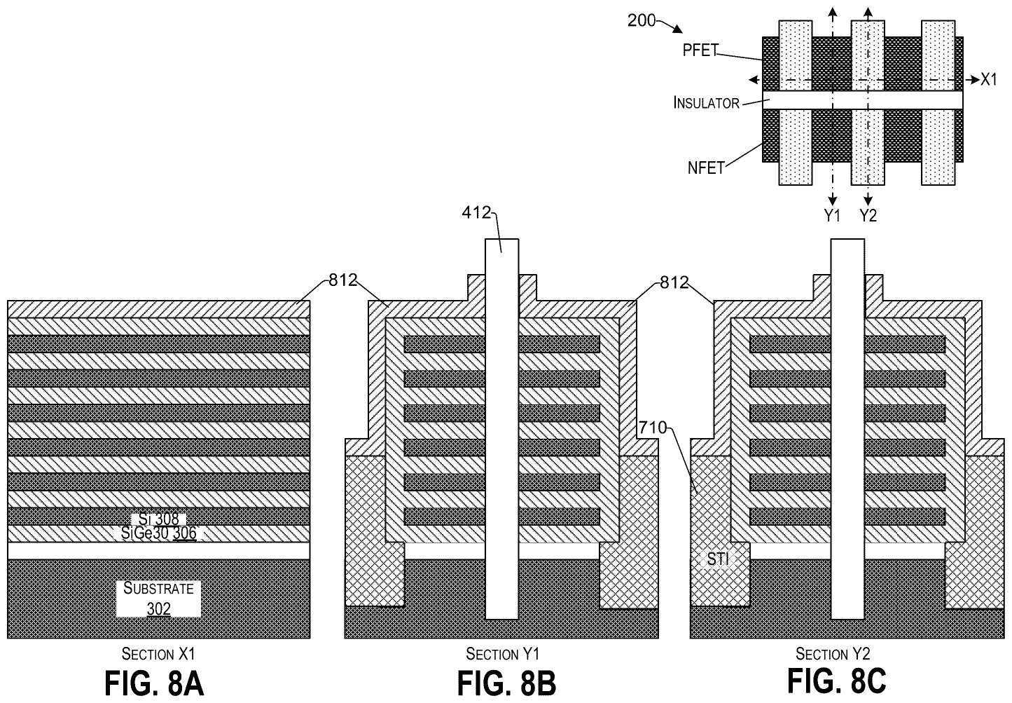

FIGS. 8A, 8B, and 8C depict a cross-section view of a semiconductor device along the lines X1, Y1, and Y2, respectively, of FIG. 2, after removal of the hard mask (HM) layer 320, consistent with an illustrative embodiment. In various embodiments, the hard mask (HM) can be removed via wet or dry etching process.

Additionally, FIGS. 8A, 8B, and 8C illustrate the formation for a sacrificial gate liner 812 on top of the top surface of the nanosheet stack and the STI 710. As is illustrated, the top portion of the vertical insulator pillar 412 is cleared from the sacrificial liner 812 by, for example, deep chamfering, discussed in more detail below.

In some embodiments, the sacrificial gate liner 812 is conformally deposited over the nanosheet stack. The sacrificial gate liner 812 may have a thickness greater than the sacrificial layers 110, for example, of about 8 nm to about 20 nm, although other thicknesses are within the contemplated scope of the disclosure.

In some embodiments, the sacrificial gate liner 812 is formed using chemical vapor deposition (CVD), plasma-enhanced CVD (PECVD), ultrahigh vacuum chemical vapor deposition (UHVCVD), rapid thermal chemical vapor deposition (RTCVD), metalorganic chemical vapor deposition (MOCVD), low-pressure chemical vapor deposition (LPCVD), limited reaction processing CVD (LRPCVD), atomic layer deposition (ALD), physical vapor deposition (PVD), chemical solution deposition, molecular beam epitaxy (MBE), or other like process in combination with a wet or dry etch process. The sacrificial gate liner 812 can be made of any suitable sacrificial material, such as silicon germanium (SiGe), although other sacrificial materials are within the contemplated scope of the disclosure. The sacrificial gate liner 812 may be provided as a blanket on the entire device (not shown), a second sacrificial material is deposited that leaves out a top portion of the vertical insulator pillar 412 and the sacrificial liner thereon. Deep chamfering (e.g., by way of dry etch or wet etch) can be used to remove the sacrificial gate liner 812 from the top portion of the vertical insulator pillar 412, thereby separating the left side (e.g., pFET) and the right side (e.g., nFET) of the device, as illustrated in FIGS. 8B and 8C. The second sacrificial material may then be removed, thereby providing the structure depicted in FIGS. 8A to 8C.

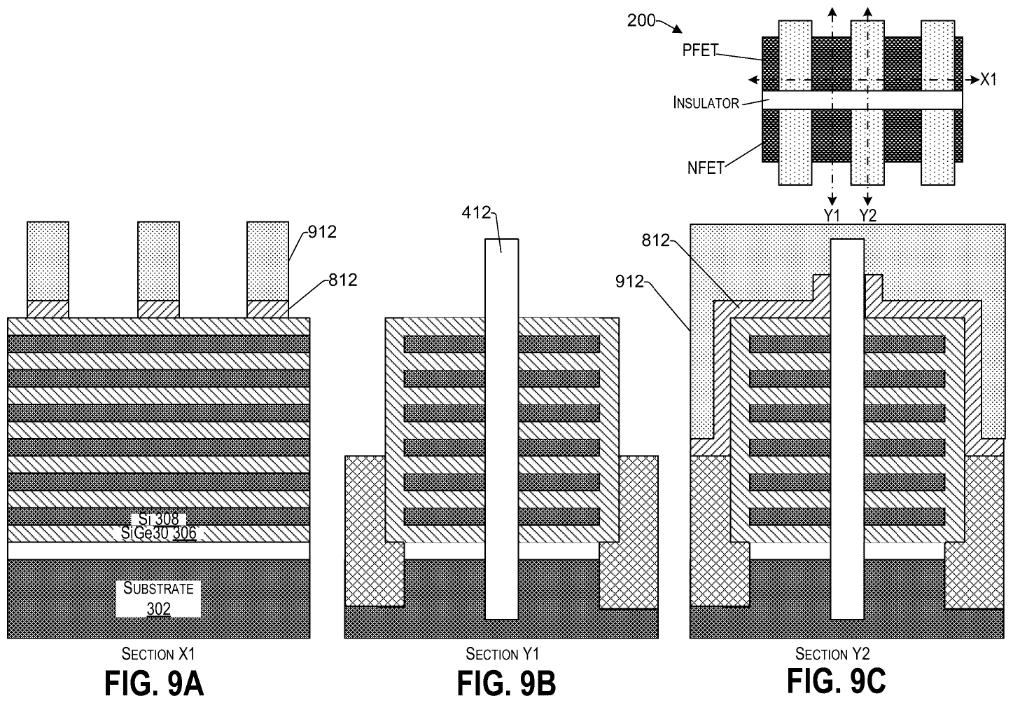

FIGS. 9A, 9B, and 9C depict a cross-section view of a semiconductor device along the lines X1, Y1, and Y2, respectively, of FIG. 2, after a gate deposition and gate patterning, consistent with an illustrative embodiment. As shown in the cross-sectional views X1 of FIG. 9A and Y2 of FIG. 9C, a dielectric gate structure 912 is formed over the sacrificial gate liner 812. The dielectric gate structure 912 can be made of any suitable dielectric material, such as, for example, low-k dielectrics (materials having a small dielectric constant relative to silicon dioxide, i.e., less than about 3.9), ultra-low-k dielectrics (materials having a dielectric constant less than 3.0), porous silicates, carbon doped oxides, silicon dioxides, silicon nitrides, silicon oxynitrides, silicon carbide (SiC), or other dielectric materials. Any known manner of forming the dielectric gate structure 912 can be utilized, such as, for example, CVD, PECVD, ALD, flowable CVD, spin-on dielectrics, or PVD. In some embodiments, the semiconductor structure of FIGS. 9A, 9B, and 9C is planarized, using, for example, a chemical-mechanical planarization (CMP) process.

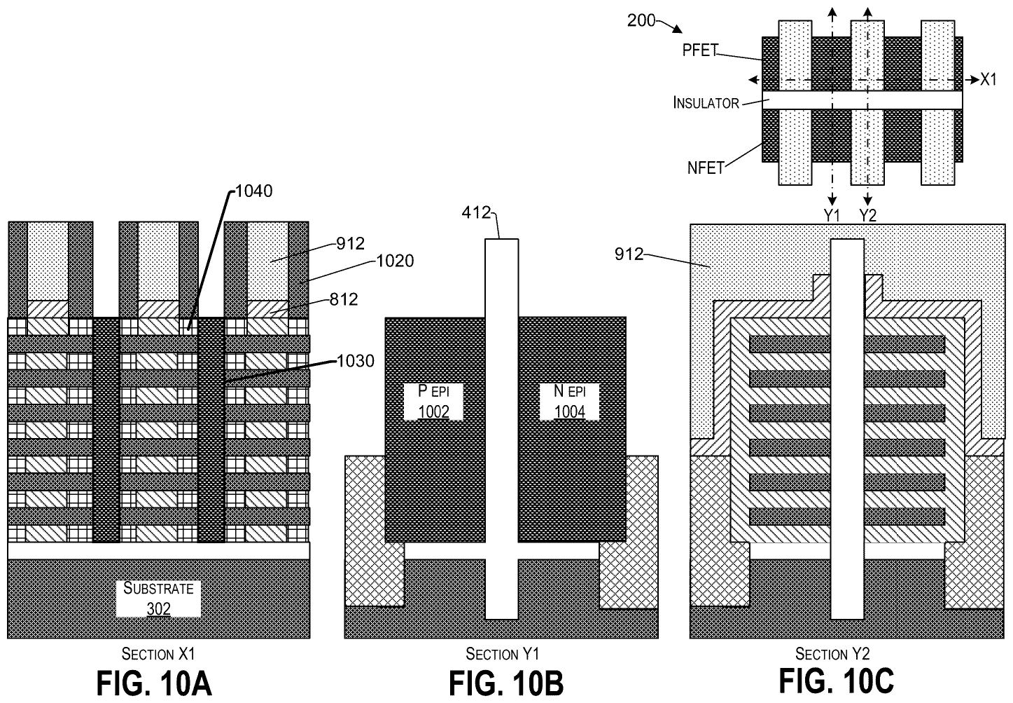

FIGS. 10A, 10B, and 10C depict a cross-section view of a semiconductor device along the lines X1, Y1, and Y2, respectively, of FIG. 2, after formation of gate spacers 1020, inner spacer 1040 and source and drain epitaxial 1002/1004 formation, consistent with an illustrative embodiment. The gate spacers 1020 can be formed on the recessed sidewalls of the dielectric gate structure 912 and the sacrificial gate liner. In some embodiments, the gate spacers 1020 are formed using a CVD, PECVD, ALD, PVD, chemical solution deposition, or other like processes in combination with a wet or dry etch process. The inner spacers 1020 can be made of any suitable material, such as, for example, a low-k dielectric, a nitride, silicon nitride, silicon dioxide, SiON, SiC, SiOCN, or SiBCN. After that, the NS stack is recessed, followed by SiGe (306) indentation, and inner spacer 1040 formation.

In some embodiments, the source and drain regions 1002 and 1004 are formed on exposed sidewalls of the third nanosheet material (e.g., nanosheet layer) 308, abuts the vertical insulator pillar 412. The source and drain regions 1002 and 1004 can be epitaxially grown using, for example, vapor-phase epitaxy (VPE), molecular beam epitaxy (MBE), liquid-phase epitaxy (LPE), or other suitable processes. For example, the source and drain regions 1002 and 1004 can be semiconductor materials epitaxially grown from gaseous or liquid precursors.

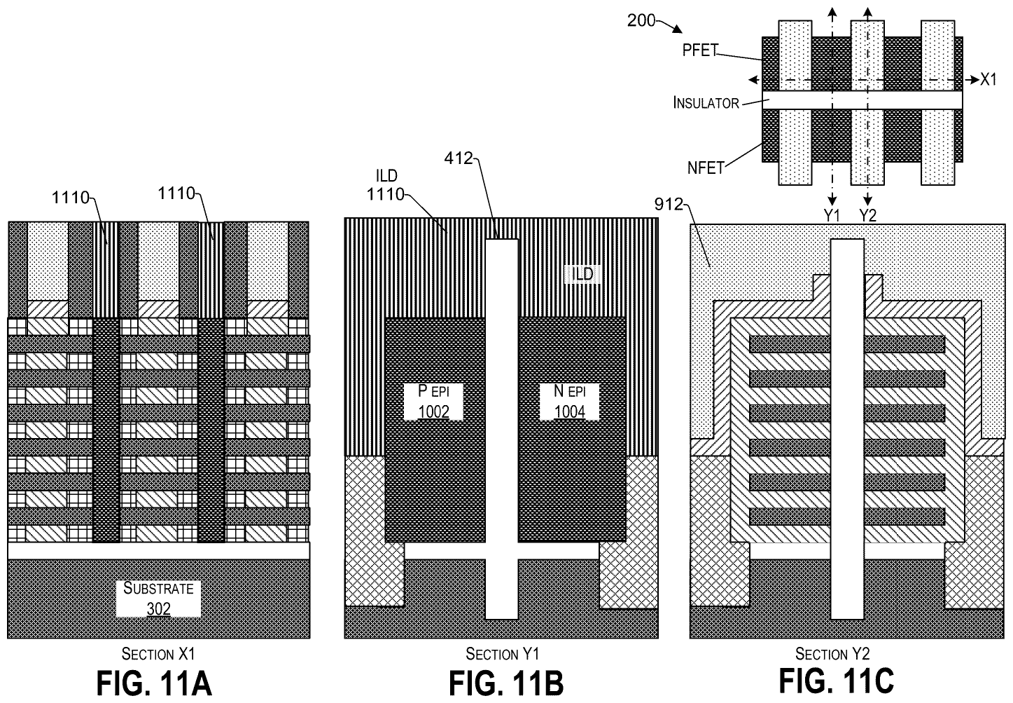

FIGS. 11A, 11B, and 11C depict a cross-section view of a semiconductor device along the lines X1, Y1, and Y2, respectively, of FIG. 2, after an interlayer dielectric 1110 deposition, consistent with an illustrative embodiment. For example, the interlayer dielectric (ILD) 1110 is formed over the source and drain regions 1002 and 1004. The ILD 1110 can be made of any suitable dielectric material, such as, for example, oxides, a low-k dielectric, nitrides, silicon nitride, silicon oxide, SiON, SiC, SiOCN, and SiBCN. In some embodiments, the ILD 1110 is deposited over the semiconductor structure, which is then planarized using, for example, chemical mechanical polishing (CMP).

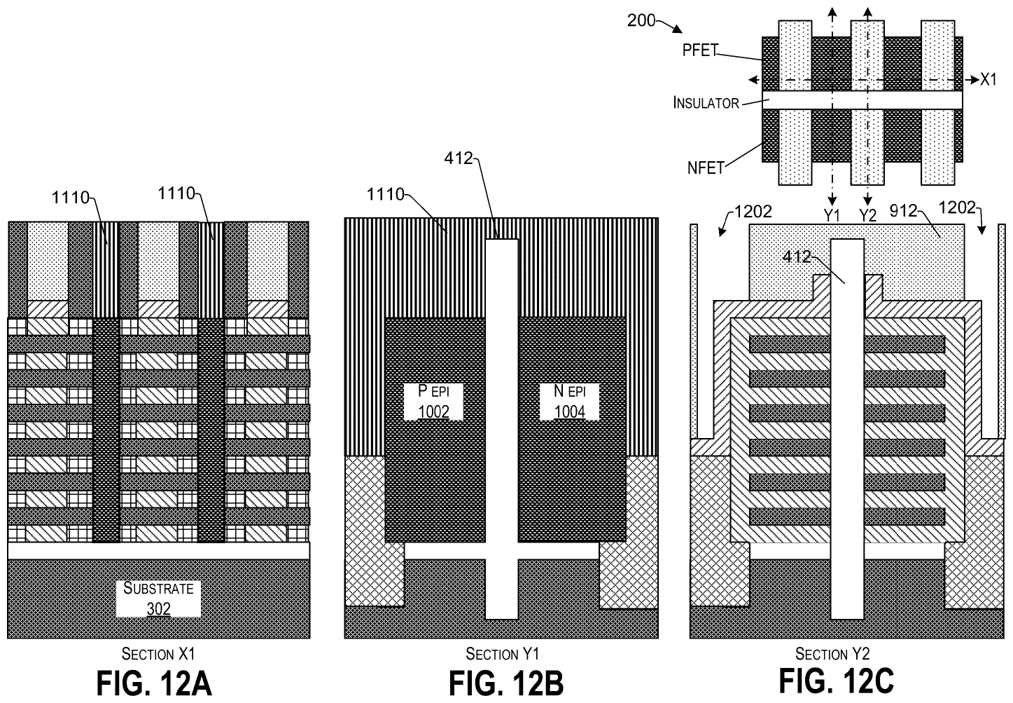

FIGS. 12A, 12B, and 12C depict a cross-section view of a semiconductor device along the lines X1, Y1, and Y2, respectively, of FIG. 2, after trench openings 1202 are created, consistent with an illustrative embodiment. In this regard, FIG. 12C illustrates openings (or trenches) 1202, sometimes referred to herein as a replacement gate opening, created on both sides of the middle pillar, effectively removing portions of the dielectric gate structure 912. These openings 1202 provide access to the gate of each transistor device (e.g., pFET and nFET, respectively). In some embodiments, the gate trench opening 1202 is formed by removing portions of the dielectric gate structure 912 to define a trench 1202 exposing a portion of the surface of the sacrificial gate liner 812 on each side of the vertical insulator pillar 412. The trench 1202 can be patterned, for example, using photolithography followed by a dry etch, or a combination of sequential dry and/or wet etches

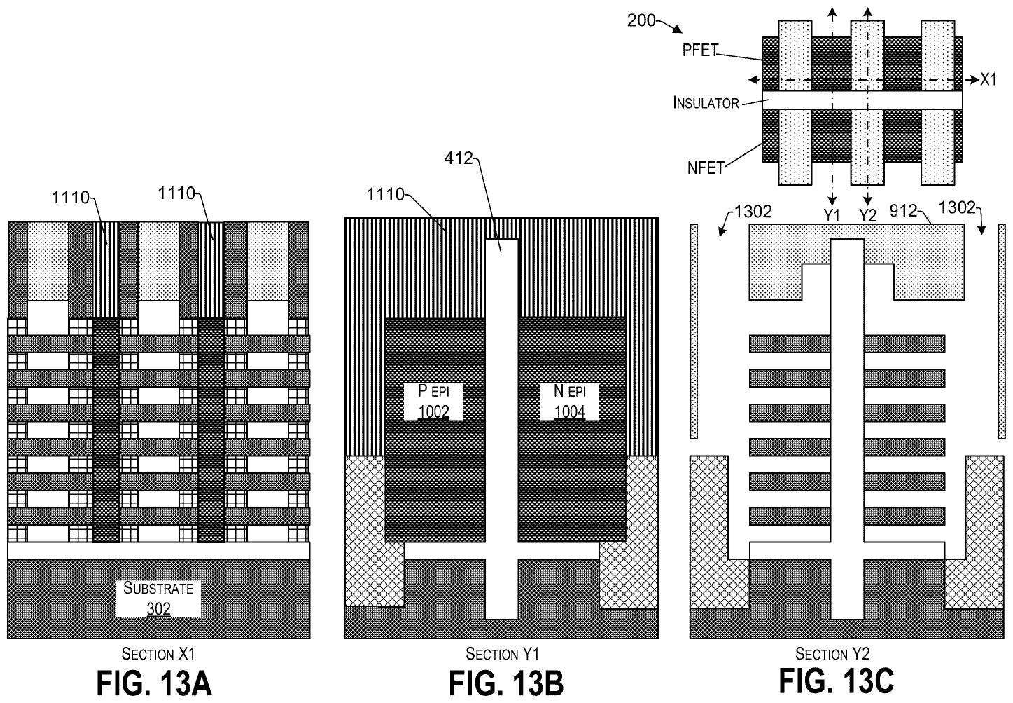

FIGS. 13A, 13B, and 13C depict a cross-section view of a semiconductor device along the lines X1, Y1, and Y2, respectively, of FIG. 2, after a sacrificial gate liner 812 and SiGe of the SiGe growth 610 as well as the second nanosheet layer 306 (e.g., SiGe30) of the nanosheet gate stack are removed, consistent with an illustrative embodiment. For example, the sacrificial gate liner 812, the SiGe growth 610, as well as the second nanosheet layer 306 can be removed (sometimes referred to as a stack recess) to define a gate patterning trench that exposes top, bottom, and a first side surface (opposite to that of the vertical insulator pillar 412) of the third nanosheet material 308 (e.g., Si). The aforementioned layers can be selectively removed using any suitable technique, thereby resulting in the openings (e.g., cavity) 1302 and exposed channels depicted in FIG. 13C. For example, carboxylic acid/nitric acid/HF chemistry, citric acid/nitric acid/HF, and vapor phased HCl, for example, can be utilized to remove SiGe 30 selective to silicon. In another example, aqueous hydroxide chemistry, including ammonium hydroxide and potassium hydroxide, can be utilized to remove silicon selective to SiGe.

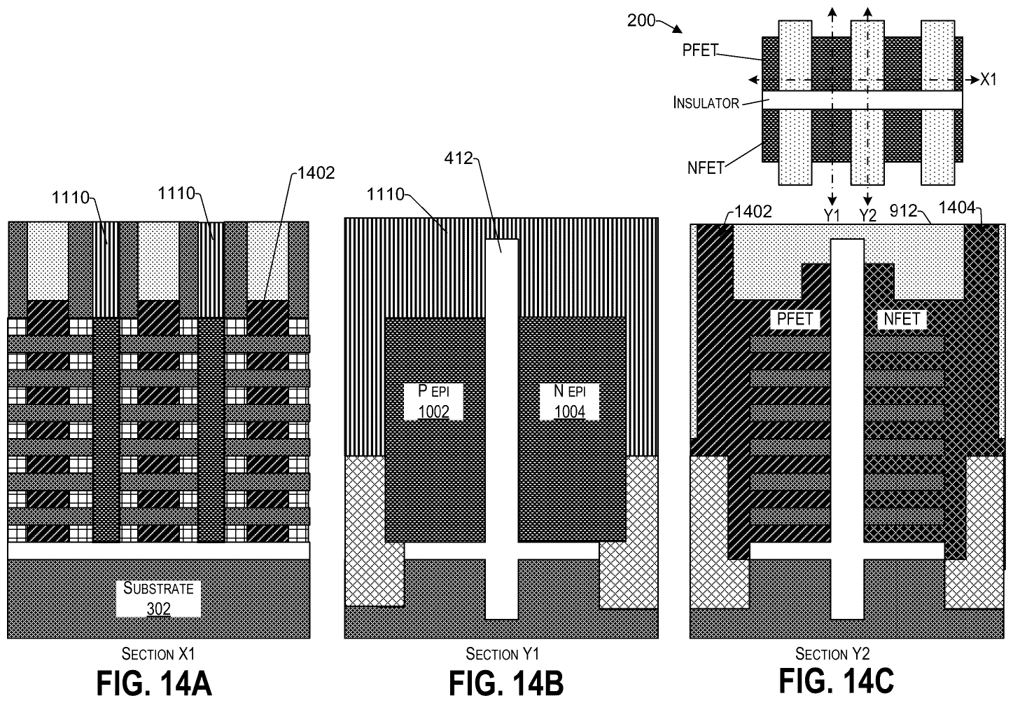

FIGS. 14A, 14B, and 14C depict a cross-section view of a semiconductor device along the lines X1, Y1, and Y2, respectively, of FIG. 2, after a high-k metal gate (HKMG) formation, consistent with an illustrative embodiment. For example, the pFET and nFET gates 1402 and 1404, respectively, (sometimes referred to herein as an pFET gate stack and an nFET gate stack) can be high-k metal gates (HKMGs) formed over a channel region of the nanosheet. The gates 1402 and 1404 are sometimes referred to as metal gates or conductive gates. In some embodiments, the gates 1402 and 1404 are formed by depositing high-k/metal gate materials into the cavity 1302 (shown in FIG. 13C). Significantly, the work function metal (WFM) patterning is facilitated because the larger distance between the top openings for the pFET 1402 and the nFET 1404 are large (e.g., greater than 30 nm, which provides very robust litho process window for WFM patterning).

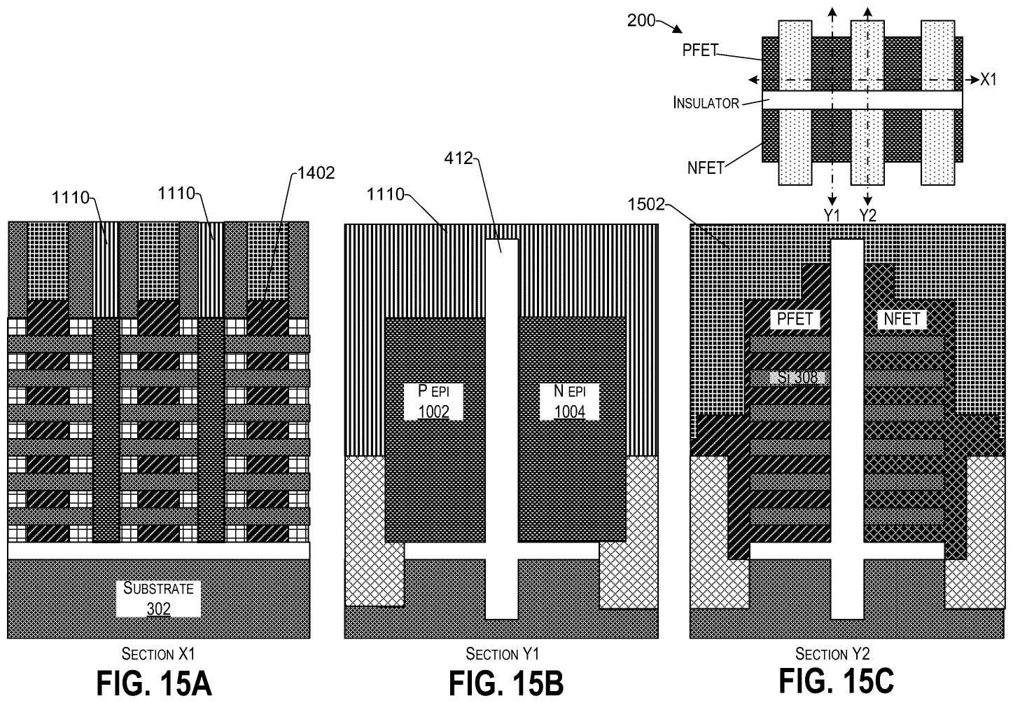

FIGS. 15A, 15B, and 15C depict a cross-section view of a semiconductor device along the lines X1, Y1, and Y2, respectively, of FIG. 2, after excess metal is recessed and a self-aligned contact (SAC) cap 1502 is formed, consistent with an illustrative embodiment. In various embodiments, the SAC cap 1502 may comprise SiO2, SiN, SiOC, silicon oxycarbonitride (SiOCN), silicoboron carbonitride (SiBCN), or any other suitable material.

FIGS. 16A, 16B, and 16C depict a cross-section view of a semiconductor device along the lines X1, Y1, and Y2, respectively, of FIG. 2, after additional processing for separate gate devices, consistent with an illustrative embodiment. For example, the gate contacts (CB) 1604 and the source/drain contact (TS) 1602 are formed. As is illustrated in FIG. 16C, there is a separate gate contact 1604 (CB) for the pFET and nFET portion of the semiconductor structure.

FIG. 16D provides an enlarged view of FIG. 16C, consistent with an illustrative embodiment. The structure of FIG. 16D illustrates a vertical insulator pillar 412 extending from the substrate 302. There is a first stack of horizontal sheets (e.g., 308) of a first channel device (e.g., pFET) coupled to a lateral first side of the vertical insulator pillar 412. There is a second stack of horizontal sheets (e.g., 308) of a second channel device (nFET) coupled to a lateral second side of the vertical insulator pillar 412, opposite the first stack of horizontal sheets (of the pFET). A first gate stack 1610 is wrapped around the first stack of horizontal sheets (e.g., 308 of pFET) and a second gate stack 1620 is wrapped around the second stack of horizontal sheets (e.g., 308 of nFET). A first gate extension 1612 is coupled to a center portion of the first gate stack 1610 and extending laterally away from the second gate stack 1620. There is a second gate extension 1622 coupled to a center portion of the second gate stack 20 and extending laterally away from the first gate stack 1610. By virtue of having the first gate extension 1612 and the second gate extension 1622 at the center of the corresponding gate stack (e.g., 1610 and 1620), there is less resistance and a more uniform signal path between a gate contact (e.g., 1604) and its corresponding gate stack (1610 or 1620).

In the example of FIG. 16D, there is a first gate contact 1604 (CB) extending from a top of the semiconductor device to the first gate extension 1612, and a second gate contact 1605 extending from the top of the semiconductor device to the second gate extension 1622. In some embodiments, at least a portion of the vertical insulator pillar 412 is embedded in the substrate 302.

In the embodiment of FIG. 16D, there is a third extension 1630 on a top portion of the first gate stack 1610 abutting the vertical insulator pillar 160, and a fourth extension 1632 on a top portion of the second gate stack 1620 abutting the vertical insulator pillar 412.

In one embodiment, a lateral side width of the first gate stack 1610 overlapping from the first stack of horizontal sheets is substantially similar to a gap between each of the sheets of the first stack of horizontal sheets. A lateral side width of the second gate stack overlapping from the second stack 1620 of horizontal sheets is also substantially similar to a gap between each of the sheets of the second stack of horizontal sheets (nFET).

It is noted that there is a shallow trench isolation (STI) 710 extending from the substrate to a middle portion of the first gate stack 1610 and the second gate stack 1620. In this way, a gate contact (e.g., 1604) that is not excessively deep can be facilitated, thereby simplifying processing complexity, as well as allowing the gate to be controlled in a more resistively uniform way, as explained above.

By way of contrast, FIGS. 17A, 17B, and 17C depict a cross-section view of a semiconductor device along the lines X1, Y1, and Y2, respectively, of FIG. 2, for shared gate devices, consistent with an illustrative embodiment. For example, the gate contacts (CB) 1604, 1605 and the source/drain contact (TS) are formed. As is illustrated in FIG. 17C, there is a single gate contact 1702 that is shared by the gate of the pFET and nFET. There are gate cut regions 1705 on the left and right sides of the semiconductor structure depicted in FIG. 17C. For example, these gate cut regions 1705 can be formed by patterning and dielectric fill.

FIG. 17D provides an enlarged view of FIG. 17C, consistent with an illustrative embodiment. In the example of FIG. 17D, there is a common gate contact 1702 coupled to a top portion of the third extension 1630 of the first gate stack 1610, a top portion of the fourth extension 1632 of the second gate stack 1620, and a top of the center vertical pillar 412.

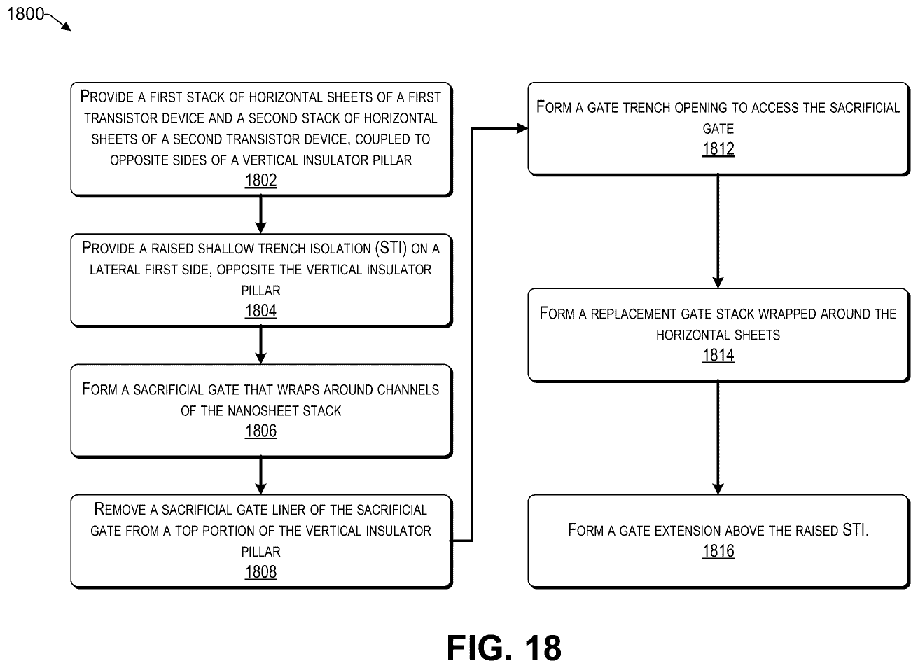

As is illustrated in the resulting structures depicted in FIGS. 16D and 17D, in contrast to the forksheet device 100B of FIG. 1B, the teachings herein provide substantially less metallization of the HKMG material of the gates 1402 and 1404, thereby substantially reducing the parasitic capacitance between a gate contact 1604, 1605 (e.g., CB) and its corresponding gate structure. The sidewall of the HKMG of the gate of each transistor (e.g., pFET and/or nFET) largely follows the contour of the vertical insulator pillar 412 and the third nanosheet material (e.g., silicon) 308 of the nanosheet stack. There is an extension of the HKMG material of the gates 1402 and 1404 in a vertically middle portion of the nanosheet stack to provide a connection point to the gate contact 1604, 1605 (e.g., to reduce and provide a balanced resistance to the channel as opposed to providing the extension on a top or bottom portion of the pFET and nFET transistor devices.) Reference now is made to FIG. 18, which illustrates an example of method of manufacturing a semiconductor device, consistent with an illustrative embodiment. At block 1802 a first stack of horizontal sheets of a first transistor device and a second stack of horizontal sheets of a second transistor device, coupled to opposite sides of a vertical insulator pillar, are provided.

The following acts are performed for each of the first and second stack of horizontal sheets. At block 1804, a raised shallow trench isolation (STI) on a lateral first side, opposite the vertical insulator pillar is provided. At block, 1806, a sacrificial gate that wraps around channels of the nanosheet stack is formed. At block a sacrificial gate liner of the sacrificial gate from a top portion of the vertical insulator pillar, is removed.

At block 1812 a gate trench opening is formed to access the sacrificial gate. At block 1814, a replacement gate stack wrapped around the horizontal sheets is formed. At block 1816, a gate extension above the raised STI.

In one aspect, the method and structures as described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### CONCLUSION

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a substrate;
a vertical insulator pillar extending from the substrate;
a first stack of horizontal sheets of a first channel device coupled to a lateral first side of the vertical insulator pillar;
a second stack of horizontal sheets of a second channel device coupled to a lateral second side of the vertical insulator pillar, opposite the first stack of horizontal sheets;
a first gate stack wrapped around the first stack of horizontal sheets;
a second gate stack wrapped around the second stack of horizontal sheets;
a first gate extension coupled to a center portion of the first gate stack and extending laterally away from the second gate stack; and
a second gate extension coupled to a center portion of the second gate stack and extending laterally away from the first gate stack.

2. The semiconductor device of claim 1, further comprising:
a first gate contact extending from a top of the semiconductor device to the first gate extension; and
a second gate contact extending from the top of the semiconductor device to the second gate extension.

3. The semiconductor device of claim 1, wherein at least a portion of the vertical insulator pillar is embedded in the substrate.

4. The semiconductor device of claim 1, further comprising:
a third extension on a top portion of the first gate stack abutting the vertical insulator pillar; and
a fourth extension on a top portion of the second gate stack abutting the vertical insulator pillar.

5. The semiconductor device of claim 4, further comprising a common gate contact coupled to a top portion of the third extension on the top of the gate stack, a top portion of the fourth extension on the top of the gate stack, and a top of the vertical insulator pillar.

6. The semiconductor device of claim 5, further comprising:
a first gate cut region adjacent the first gate stack and extending from a top of the semiconductor device to a first shallow trench isolation (STI) on top of the substrate; and
a second gate cut region adjacent the second gate stack and extending from the top of the semiconductor device to a second shallow trench isolation (STI) on top of the substrate.

7. The semiconductor device of claim 1, wherein the first stack and the second stack of horizontal sheets each comprise a Silicon Germanium (SiGe) nanosheet stack.

8. The semiconductor device of claim 1, wherein:
a lateral side width of the first gate stack overlapping from the first stack of horizontal sheets is substantially similar to a gap between each of the sheets of the first stack of horizontal sheets; and
a lateral side width of the second gate stack overlapping from the second stack of horizontal sheets is substantially similar to a gap between each of the sheets of the second stack of horizontal sheets.

9. The semiconductor device of claim 1, further comprising a shallow trench isolation (STI) extending from the substrate to a middle portion of the first gate stack and the second gate stack.

10. The semiconductor device of claim 1, wherein:
the semiconductor device is a forksheet device;
the first channel device is a p-channel field effect transistor (pFET); and
the second channel device is an n-channel field effect transistor (nFET).

11. The semiconductor device of claim 1, wherein a width of the vertical insulator pillar is below 10 nm.

12. The semiconductor device of claim 1, wherein the first gate stack is not directly coupled to the second gate stack and is separated by the vertical insulator pillar.

13. A method of manufacturing a semiconductor device, comprising:
providing a first stack of horizontal sheets of a first transistor device and a second stack of horizontal sheets of a second transistor device, coupled to opposite sides of a vertical insulator pillar;
for each of the first and second stack of horizontal sheets:
providing a raised shallow trench isolation (STI) on a lateral first side, opposite the vertical insulator pillar;
forming a sacrificial gate that wraps around channels of the stack of horizontal sheets; and
removing a sacrificial gate liner of the sacrificial gate from a top portion of the vertical insulator pillar;
for each of the first and second stack of horizontal sheets:
forming a gate trench opening to access the sacrificial gate;
forming a replacement gate stack wrapped around the horizontal sheets; and
forming a gate extension above the raised STI.

14. The method of claim 13, wherein:
the first transistor is a p-channel field effect transistor (pFET);
the second transistor is an n-channel field effect transistor (nFET); and
the first stack and the second stack of horizontal sheets each comprise a Silicon Germanium (SiGe) nanosheet stack.

15. The method of claim 13, wherein the sacrificial gate liner from the top portion of the vertical insulator pillar is removed by chamfering.

16. The method of claim 13, further comprising:
providing a first gate contact between a top surface of the semiconductor device and the gate extension of the first stack of horizontal sheets; and
providing a second gate contact between the top surface of the semiconductor device and the gate extension of the second stack of horizontal sheets.

17. The method of claim 13, embedding at least a portion of the vertical insulator pillar in a substrate of the semiconductor device.

18. The method of claim 13, further comprising, for each of the first and second stack of horizontal sheets, providing an additional extension on a top portion of the replacement gate stack, abutting the vertical insulator pillar.

19. The method of claim 13, further comprising, forming a common gate contact coupled to a top portion of each gate stack and a top of the vertical insulator pillar.

20. A forksheet device, comprising:
a vertical insulator pillar;
a first stack of horizontal sheets of a p-channel field effect transistor (pFET) coupled to a lateral first side of the vertical insulator pillar;
a second stack of horizontal sheets of a n-channel field effect transistor (nFET) coupled to a lateral second side of the vertical insulator pillar, opposite the first stack of horizontal sheets;
a first gate stack wrapped around the first stack of horizontal sheets;
a second gate stack wrapped around the second stack of horizontal sheets;
a first gate extension coupled to a center portion of the first gate stack and extending laterally away from the second gate stack; and
a second gate extension coupled to a center portion of the second gate stack and extending laterally away from the first gate stack.
